(19) United States
(12) Patent Application Publication
(10) Pub. No.: US 2018/0047542 A1
(43) Pub. Date: Feb. 15, 2018

(54) INDUCTIVELY COUPLED PLASMA CHAMBER HAVING A MULTI-ZONE SHOWERHEAD

(71) Applicant: Applied Materials, Inc., Santa Clara, CA (US)

(72) Inventors: ANDREW NGUYEN, San Jose, CA (US); XUE CHANG, San Jose, CA (US)

(21) Appl. No.: 15/675,682

(22) Filed: Aug. 11, 2017

Related U.S. Application Data
(60) Provisional application No. 62/374,835, filed on Aug. 13, 2016.

(51) Int. Cl. H01J 37/32

(52) U.S. Cl. CPC H01J 37/3244; H01J 37/321

(57) ABSTRACT

Apparatus for plasma processing are provided herein. In some embodiments, a process chamber includes: a chamber body having a processing volume within; a dielectric adapter ring disposed atop the chamber body; a multi-zone showerhead disposed atop the dielectric adapter ring to provide process gas to the processing volume; and an inductively-coupled RF coil disposed about an upper portion of the chamber body to couple RF energy to the processing volume.

### CROSS-REFERENCE TO RELATED APPLICATIONS

This application claims the benefit of U.S. Provisional Patent Application No. 62/374,835, filed with the United States Patent Office on Aug. 13, 2016, which is herein incorporated by reference in its entirety.

### FIELD

Embodiments of the present disclosure generally relate to plasma processing equipment.

### BACKGROUND

Inductively coupled plasma (ICP) process chambers generally form plasmas by inducing current in a process gas disposed within the process chamber via one or more inductive coils disposed outside of the process chamber. The inductive coils may be disposed externally and separated electrically from the chamber by, for example, a dielectric lid. When radio frequency (RF) current is fed to the inductive coils via an RF feed structure from an RF power supply, an inductively coupled plasma can be formed inside the chamber from an electric field generated by the inductive coils.

In some reactor designs, the reactor may be configured to have concentric inner and outer inductive coils. RF power from an RF power source may be split between the two coils via a current divider/variable capacitor, or the like. The RF power is coupled from the antenna or electrode to process gases within the reactor to form a plasma that is used for the etching process. The matching network ensures that the output of the RF source is efficiently coupled to the plasma to maximize the amount of energy coupled to the plasma (e.g., referred to as tuning the RF power delivery).

Existing reactor designs often flow gas through a nozzle disposed at the center of the dielectric lid. However, the inventors have observed that such a chamber configuration sometimes results in m-shaped deposition on the substrate being processed.

Accordingly, the inventors have devised an improved process chamber.

### SUMMARY

Apparatus for plasma processing are provided herein. In some embodiments, a process chamber includes: a chamber body having a processing volume within; a dielectric adapter ring disposed atop the chamber body; a multi-zone showerhead disposed atop the dielectric adapter ring to provide process gas to the processing volume; and an inductively-coupled RF coil disposed about an upper portion of the chamber body to couple RF energy to the processing volume.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a process chamber in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Apparatus for plasma processing are provided herein. The inventive apparatus includes one or more inductive coils surrounding the processing volume and a multi-zone showerhead which, together, advantageously improve gas distribution and deposition uniformity on the substrate being processed. The configuration of the inventive apparatus advantageously eliminates the m-shaped deposition that results from conventional inductively coupled plasma processing chambers. Due to the increased surface area compared with the conventional central gas nozzle, the multi-zone showerhead provides a more uniform gas distribution in the process chamber.

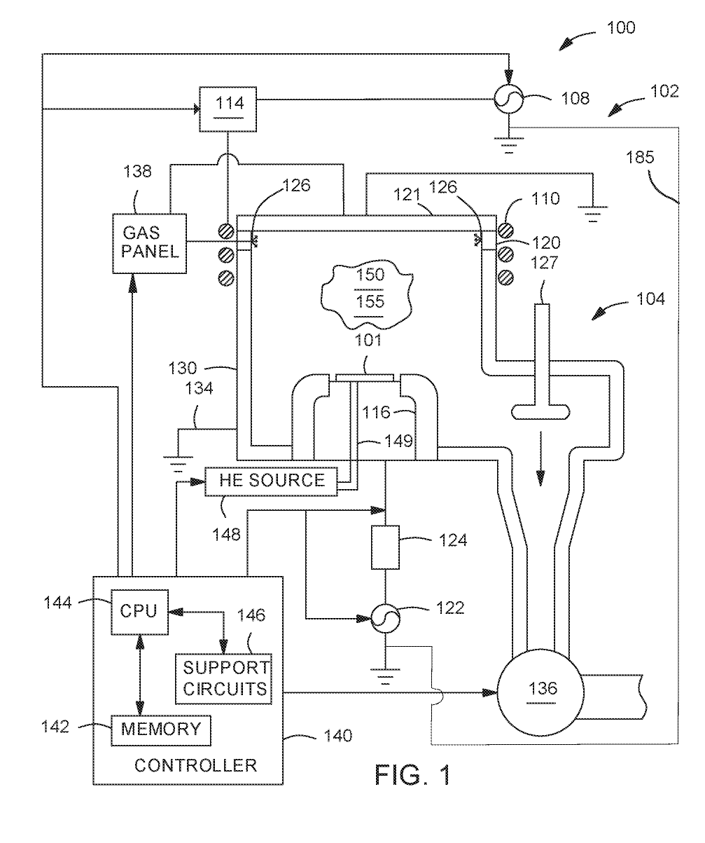

FIG. 1 depicts a schematic side view of an exemplary inductively coupled plasma reactor (reactor 100) in accordance with some embodiments of the present disclosure. Although embodiments consistent with the present disclosure are described herein with respect to inductively coupled plasma reactor, embodiments consistent with the present disclosure may be used in conjunction with any chamber with an inductive coupled plasma chamber.

The reactor 100 may be utilized alone or, as a processing module of an integrated semiconductor substrate processing system, or cluster tool, such as a CENTRIS™ SYM3™ integrated semiconductor wafer processing system, available from Applied Materials, Inc. of Santa Clara, Calif. Examples of suitable plasma reactors that may advantageously benefit from modification in accordance with embodiments of the present disclosure include inductively coupled plasma etch reactors such as the MESA™, CENTURA® or DPS® line of semiconductor equipment (such as the DPS®, DPS® II, DPS® AE, DPS® G3 poly etcher, DPS® G5, or the like) also available from Applied Materials, Inc. The above listing of semiconductor equipment is illustrative only, and other etch reactors, and non-etch equipment (such as CVD reactors, or other semiconductor processing equipment) may also be suitably modified in accordance with the present teachings.

The reactor 100 includes an inductively coupled plasma apparatus 102 disposed about a process chamber 104. The inductively coupled plasma apparatus includes an RF feed structure for coupling an RF power supply 108 to a one or more RF coils, e.g., RF coil 110. The RF coil 110 is coaxially disposed about an upper portion of the process chamber 104 and is configured to inductively couple RF power into the process chamber 104 to form a plasma from process gases provided within the process chamber 104. The RF power supply 108 is coupled to the RF feed structure via a match network 114.

The reactor 100 generally includes the process chamber 104 having a conductive body (wall 130) and a dielectric adapter ring 120 on which a multi-zone showerhead 121 is disposed (all of which define a processing volume). The process chamber further includes a substrate support 116 disposed within the processing volume, the inductively coupled plasma apparatus 102, and a controller 140. The wall 130 is typically coupled to an electrical ground 134. In some embodiments, the substrate support 116 may provide a cathode coupled through a matching network 124 to a biasing power source 122. The biasing power source 122 may illustratively be a source of up to 1000 W at a frequency of approximately 13.56 MHz that is capable of producing either continuous or pulsed power, although other higher or lower frequencies and powers may be provided as desired for particular applications. In other embodiments, the biasing power source 122 may be a DC or pulsed DC source.

In some embodiments, a link 185 may be provided to couple the RF power supply 108 and the biasing power source 122 to facilitate synchronizing the operation of one source to the other. Either RF source may be the lead, or master, RF generator, while the other generator follows, or is the slave. The link 185 may further facilitate operating the RF power supply 108 and the biasing power source 122 in perfect synchronization, or in a desired offset, or phase difference. The phase control may be provided by circuitry disposed within either or both of the RF power sources or within the link between the RF power sources. The phase control between the source and bias RF generators (e.g., 108, 122) may be provided and controlled independent of the phase control over the RF current flowing in the RF coil coupled to the RF power supply 108.

The inductively coupled plasma apparatus 102 includes the RF coil 110 disposed about an upper portion of the process chamber 104, specifically, about the dielectric adapter ring 120. The relative position, diameter of the coil, and/or the number of turns in the coil can each be adjusted as desired to control, for example, the profile or density of the plasma being formed via controlling the inductance on each coil. The RF coil 110 is coupled through the matching network 114 to the RF power supply 108. The RF power supply 108 may illustratively be capable of producing up to 4000 W at a tunable frequency in a range from 50 kHz to 13.56 MHz, although other higher or lower frequencies and powers may be provided as desired for particular applications.

During operation, a substrate 101 (such as a semiconductor wafer or other substrate suitable for plasma processing) may be placed on the substrate support 116 and process gases may be supplied from a gas panel 138 through the multi-zone showerhead 121 to form a gaseous mixture 150 within the process chamber 104. In some embodiments, the process chamber 104 may also include gas inlet ports 126 disposed in the wall 130 or through the dielectric adapter ring 120 to provide additional process gas into the processing volume from the sides of the chamber. The gaseous mixture 150 may be ignited into a plasma 155 in the process chamber 104 by applying power from the RF power supply 108 to the RF coil 110 and optionally, one or more electrodes (not shown). The size and shape of the dielectric adapter ring 120 may be varied to provide more control of the electric field within the process chamber 104. For example, the dielectric adapter ring 120 may be dome-shaped to provide a more uniform electric field.

In some embodiments, power from the biasing power source 122 may be also provided to the substrate support 116. The pressure within the interior of the process chamber 104 may be controlled using a throttle valve 127 and a vacuum pump 136. The temperature of the wall 130 may be controlled using liquid-containing conduits (not shown) that run through the wall 130.

The temperature of the substrate 101 may be controlled by stabilizing a temperature of the substrate support 116. In one embodiment, helium gas from a gas source 148 may be provided via a gas conduit 149 to channels defined between the backside of the substrate 101 and grooves (not shown) disposed in the substrate support surface. The helium gas is used to facilitate heat transfer between the substrate support 116 and the substrate 101. During processing, the substrate support 116 may be heated by a resistive heater (not shown) within the substrate support to a steady state temperature and the helium gas may facilitate uniform heating of the substrate 101.

The controller 140 comprises a central processing unit (CPU) 144, a memory 142, and support circuits 146 for the CPU 144 and facilitates control of the components of the reactor 100 and, as such, of methods of forming a plasma, such as discussed herein. The controller 140 may be any form of general-purpose computer processor that can be used in an industrial setting for controlling various chambers and sub-processors. The memory, or computer-readable medium, 142 of the CPU 144 may be one or more of readily available memory such as random access memory (RAM), read only memory (ROM), floppy disk, hard disk, or any other form of digital storage, local or remote. The support circuits 446 are coupled to the CPU 144 for supporting the processor in a conventional manner. These circuits include cache, power supplies, clock circuits, input/output circuitry and subsystems, and the like. The method for forming plasma may be stored in the memory 142 as software routine that may be executed or invoked to control the operation of the reactor 100 in the manner described above. The software routine may also be stored and/or executed by a second CPU (not shown) that is remotely located from the hardware being controlled by the CPU 144. The controller 140 controls the RF power supply 108, the matching network 114, to provide the desired current through the RF coil 110.

While the foregoing is directed to embodiments of the present disclosure, other and further embodiments of the disclosure may be devised without departing from the basic scope thereof.

1. A process chamber, comprising:
a chamber body having a processing volume within;
a dielectric adapter ring disposed atop the chamber body;
a multi-zone showerhead disposed atop the dielectric adapter ring to provide process gas to the processing volume; and
an inductively-coupled radio frequency (RF) coil disposed about an upper portion of the chamber body and surrounding the dielectric adapter ring to couple RF energy to the processing volume.

2. The process chamber of claim 1, further comprising:
gas inlet ports disposed at a side of the process chamber to provide additional process gas to the processing volume.

3. The process chamber of claim 2, wherein the gas inlet ports are disposed in walls of the process chamber.

4. The process chamber of claim 2, wherein the gas inlet ports are disposed in the dielectric adapter ring.

5. The process chamber of claim 1, wherein the chamber body is electrically conductive.

6. The process chamber of claim 1, further comprising:
a substrate support disposed within the processing volume opposite the multi-zone showerhead; and
an RF power supply electrically coupled to the inductively coupled RF coil through a first matching network.

7. The process chamber of claim 6, further comprising:
a biasing power source electrically coupled to the substrate support is electrically through a second matching network.

8. The process chamber of claim 7, further comprising:
a link configured to facilitate synchronizing operation of the RF power supply and the biasing power source.

9. A process chamber, comprising:
a chamber body having a processing volume within;
a dielectric adapter ring disposed atop the chamber body;
a multi-zone showerhead disposed atop the dielectric adapter ring to provide process gas to the processing volume;
an inductively-coupled radio frequency (RF) coil disposed about an upper portion of the chamber body and surrounding the dielectric adapter ring to couple RF energy to the processing volume; and
gas inlet ports disposed at a side of the process chamber to provide additional process gas to the processing volume.

10. The process chamber of claim 9, wherein the gas inlet ports are disposed in walls of the process chamber.

11. The process chamber of claim 9, wherein the gas inlet ports are disposed in the dielectric adapter ring.

12. The process chamber of claim 9, wherein the chamber body is electrically conductive.

13. The process chamber of claim 9, further comprising:
a substrate support disposed within the processing volume opposite the multi-zone showerhead; and
an RF power supply electrically coupled to the inductively coupled RF coil through a first matching network.

14. The process chamber of claim 13, further comprising:
a biasing power source electrically coupled to the substrate support is electrically through a second matching network.

15. The process chamber of claim 14, further comprising:
a link configured to facilitate synchronizing operation of the RF power supply and the biasing power source.

16. A process chamber, comprising:
a chamber body having a processing volume within;
a dielectric adapter ring disposed atop the chamber body;
a multi-zone showerhead disposed atop the dielectric adapter ring to provide process gas to the processing volume;
a substrate support disposed within the processing volume opposite the multi-zone showerhead;
an inductively-coupled radio frequency (RF) coil disposed about an upper portion of the chamber body and surrounding the dielectric adapter ring to couple RF energy to the processing volume;
gas inlet ports disposed at a side of the process chamber to provide additional process gas to the processing volume;
an RF power supply electrically coupled to the inductively coupled RF coil through a first matching network; and
a biasing power source electrically coupled to the substrate support is electrically through a second matching network.

17. The process chamber of claim 16, wherein the gas inlet ports are disposed in walls of the process chamber.

18. The process chamber of claim 16, wherein the gas inlet ports are disposed in the dielectric adapter ring.

19. The process chamber of claim 16, wherein the chamber body is electrically conductive.

20. The process chamber of claim 16, further comprising:
a link configured to facilitate synchronizing operation of the RF power supply and the biasing power source.
